(19) United States
(12) Patent Application Publication
(10) Pub. No.: US 2023/0005792 A1
(43) Pub. Date: Jan. 5, 2023

(54) METHOD OF MANUFACTURING CHIPS

(71) Applicant: DISCO CORPORATION, Tokyo (JP)

(72) Inventor: Masatoshi WAKAHARA, Tokyo (JP)

(21) Appl. No.: 17/808,320

(22) Filed: Jun. 23, 2022

(30) Foreign Application Priority Data
Jun. 30, 2021 (JP) 2021-109570

(51) Int. Cl. H01L 21/78; H01L 21/3065; H01L 21/683; B23K 26/364

(52) U.S. Cl. CPC H01L 21/78; H01L 21/3065; H01L 21/6836; B23K 26/364

(57) ABSTRACT

A method of manufacturing chips includes a preparing step of preparing a wafer unit in which a wafer having a plurality of devices formed thereon is affixed to a tape with a die-attach layer being interposed therebetween, the die-attach layer including fillers, and the devices are protected by a protective member and a face side of the wafer is exposed along the projected dicing lines, a wafer processing step of performing plasma etching on the wafer from the face side thereof to divide the wafer and expose the die-attach layer along the projected dicing lines, a die-attach layer processing step of performing plasma etching on the die-attach layer from the face side of the wafer, and a cleaning step of ejecting a fluid to the face side of the wafer to remove filler residuals along the projected dicing lines from the wafer unit.

### BACKGROUND OF THE INVENTION

### Field of the Invention

The present invention relates to a method of manufacturing chips with laminated die-attach layers.

### Description of the Related Art

According to semiconductor device fabrication processes, a semiconductor wafer with a plurality of devices formed thereon is divided into a plurality of semiconductor devices.

Dicing apparatuses that use a cutting blade or a laser beam have been in widespread use for dividing wafers. Processes using plasma etching have also been customary to divide wafers. There has also been proposed a process for processing wafers with laminated die-attach films by way of plasma etching (see, for example, Japanese Patent Laid-open No. 2009-18797).

### SUMMARY OF THE INVENTION

In case die-attach layers are used in mounting devices on boards, a die-attach layer is formed on a wafer before the wafer is fragmented into device chips, and the wafer is divided together with the die-attach layer.

Fluorine-based gases that are widely used in plasma etching processes for dividing wafers are unable to process die-attach layers laminated on the wafers. Therefore, it has been common to divide a wafer with a laminated die-attach layer by processing the wafer by way of plasma etching and then processing the laminated die-attach layer with another dicing apparatus. Since this common practice involves an increased number of working steps, it is tedious and time-consuming and leaves much to be improved.

It is therefore an object of the present invention to provide a method of manufacturing chips with laminated die-attach layers while avoiding an increase in the number of working steps thereof.

In accordance with an aspect of the present invention, there is provided a method of manufacturing chips with laminated die-attach layers, including a preparing step of preparing a wafer unit in which a wafer having a plurality of devices formed in respective areas demarcated on a face side thereof by a plurality of intersecting projected dicing lines established thereon is affixed to a tape with a die-attach layer being interposed therebetween, the die-attach layer including fillers, the tape is mounted on an annular frame, the devices are protected by a protective member, and the face side of the wafer is exposed along the projected dicing lines; a wafer processing step of supplying a first gas to the wafer unit and performing plasma etching on the wafer from the face side thereof to divide the wafer and expose the die-attach layer along the projected dicing lines; after the wafer processing step, a die-attach layer processing step of supplying a second gas to the wafer unit and performing plasma etching on the die-attach layer from the face side of the wafer; and after the die-attach layer processing step, a cleaning step of ejecting a fluid to the face side of the wafer to remove filler residuals that have remained along the projected dicing lines in the die-attach layer processing step from the wafer unit.

Preferably, the cleaning step includes the step of ejecting the fluid to the face side of the wafer along the projected dicing lines. Preferably, the cleaning step includes the step of ejecting the fluid to the face side of the wafer while the face side of the wafer is facing downwardly.

According to the present invention, the method of manufacturing chips is advantageous in that the number of working steps required to manufacture the chips each with the laminated die-attach layer is prevented from increasing.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating by way of example a wafer as an object to be processed by a method of manufacturing chips according to a first embodiment of the present invention;

FIG. 2 is a perspective view illustrating by way of example a chip manufactured by dividing the wafer illustrated in FIG. 1;

FIG. 3 is a flowchart of a sequence of the method of manufacturing chips according to the first embodiment;

FIG. 4 is a perspective view illustrating the wafer with a die-attach layer and a tape affixed to a reverse side of a substrate in a preparing step of the method of manufacturing chips illustrated in FIG. 3;

FIG. 5 is a cross-sectional view schematically illustrating the manner in which the wafer is placed onto a spinner table of a protective film applying apparatus in the preparing step of the method of manufacturing chips illustrated in FIG. 3;

FIG. 6 is a cross-sectional view schematically illustrating the manner in which a protective film is formed on a face side of the substrate in the preparing step of the method of manufacturing chips illustrated in FIG. 3;

FIG. 7 is a perspective view schematically illustrating the manner in which part of the protective film on the face side of the substrate is removed in the preparing step of the method of manufacturing chips illustrated in FIG. 3;

FIG. 8 is an enlarged fragmentary cross-sectional view of a wafer unit prepared in the preparing step of the method of manufacturing chips illustrated in FIG. 3;

FIG. 9 is a cross-sectional view schematically illustrating a structural example of a plasma etching apparatus for carrying out a wafer processing step and a die-attach layer processing step of the method of manufacturing chips illustrated in FIG. 3;

FIG. 10 is an enlarged fragmentary cross-sectional view of the wafer unit after the wafer processing step of the method of manufacturing chips illustrated in FIG. 3;

FIG. 11 is an enlarged fragmentary cross-sectional view of the wafer unit after the die-attach layer processing step of the method of manufacturing chips illustrated in FIG. 3;

FIG. 12 is an enlarged fragmentary cross-sectional view of the wafer illustrating a cleaning step of the method of manufacturing chips illustrated in FIG. 3;

FIG. 13 is an enlarged fragmentary cross-sectional view of the wafer from which filler residuals remaining on the bottoms of dividing grooves have been removed in the cleaning step of the method of manufacturing chips illustrated in FIG. 3;

FIG. 14 is an enlarged fragmentary cross-sectional view of the wafer after a mask removing step of the method of manufacturing chips illustrated in FIG. 3;

FIG. 15 is an enlarged fragmentary cross-sectional view of the wafer illustrating a picking-up step of the method of manufacturing chips illustrated in FIG. 3; and

FIG. 16 is an enlarged fragmentary cross-sectional view of the wafer illustrating a cleaning step of a method of manufacturing chips according to a second embodiment of the present invention.

### DETAILED DESCRIPTION OF THE PREFERRED EMBODIMENTS

Preferred embodiments of the present invention will be described in detail hereinbelow with reference to the accompanying drawings. The present invention is not limited to the details of the embodiments described below. The components described below cover those which could easily be anticipated by those skilled in the art and those which are essentially identical to those described above. Further, the arrangements described below can be combined in appropriate manners. Various omissions, replacements, or changes of the arrangements may be made without departing from the scope of the present invention. In the description to be described below, those components that are identical to each other are denoted by identical reference signs, and will be omitted from description.

### First Embodiment

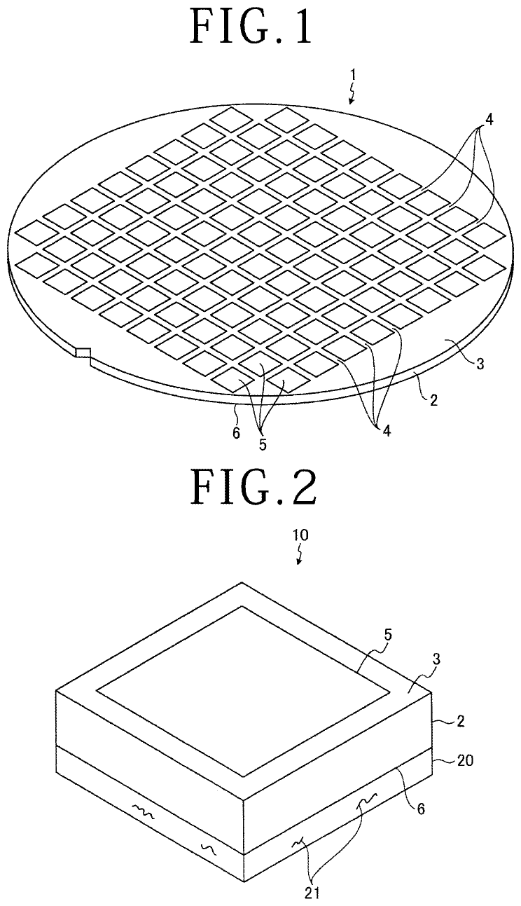

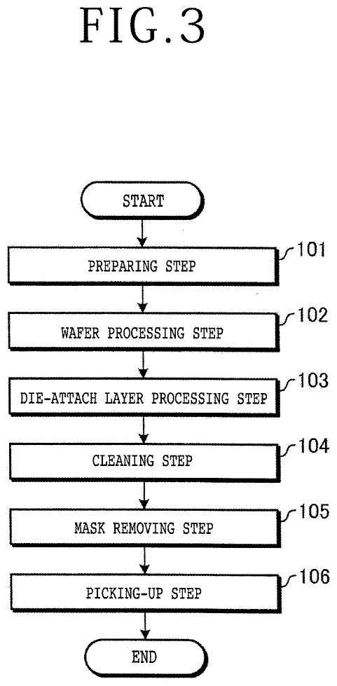

A method of manufacturing chips according to a first embodiment of the present invention will be described below with reference to the drawings. FIG. 1 illustrates in perspective by way of example a wafer as an object to be processed by the method of manufacturing chips according to the first embodiment. FIG. 2 illustrates in perspective by way of example a chip manufactured by dividing the wafer illustrated in FIG. 1. FIG. 3 is a flowchart of a sequence of the method of manufacturing chips according to the first embodiment.

The method of manufacturing chips according to the first embodiment includes a method of processing the wafer, denoted by 1 in FIG. 1. According to the first embodiment, the wafer 1 is a semiconductor wafer, an optical wafer, or the like that is shaped as a circular plate including a substrate 2 made of silicon, sapphire, gallium arsenide, or the like. As illustrated in FIGS. 1 and 2, the wafer 1 has a plurality of devices 5 formed in respective areas demarcated on a face side 3 of the substrate 2 by a plurality of intersecting projected dicing lines 4 established thereon.

Each of the devices 5 includes, for example, a microchip such as an integrated circuit (IC) or a large-scale-integration (LSI) circuit, or an image sensor such as a charge-coupled device (CCD) or a complementary metal oxide semiconductor (CMOS). The devices 5 are smaller than devices divided from wafers by a cutting process, having a size of approximately 1 mm×1 mm, for example, and lend themselves to plasma etching, also referred to as plasma dicing, for their division into individual pieces from the wafer 1.

A die-attach layer 20 (see FIG. 2) is laminated on a reverse side 6 of the wafer 1, which is opposite the face side 3. The wafer 1 will eventually be divided together with the die-attach layer 20 along the projected dicing lines 4 into individual chips 10 illustrated in FIG. 2. Each of the chips 10 includes a portion of the substrate 2 that has been divided along adjacent ones of the projected dicing lines 4 and a device 5 on the face side 3 of the divided portion of the substrate 2. A divided portion of the die-attach layer 20 is laminated on the reverse side 6 of the substrate 2. Those parts of the chip 10 that are identical to those of the wafer 1 are denoted by identical reference signs, and will be omitted from description.

The die-attach layer 20 includes an adhesive film for die bonding to attach the individual chips 10 to other chips, boards, or the like. The die-attach layer 20 includes a resin and fillers 21. According to the first embodiment, the resin included in the die-attach layer 20 includes an acrylic resin or an epoxy resin. According to the first embodiment, the fillers 21 are made of silica, aluminum oxide, or SiC.

The method of manufacturing chips according to the first embodiment includes a method of dividing the wafer 1 together with the die-attach layer 20 along the projected dicing lines 4 to manufacture the chips 10 each including the die-attach layer 20 laminated on the reverse side 6 of the substrate 2, as illustrated in FIG. 2. As illustrated in FIG. 3, the method of manufacturing chips according to the first embodiment includes a preparing step 101, a wafer processing step 102, a die-attach layer processing step 103, a cleaning step 104, a mask removing step 105, and a picking-up step 106.

### (Preparing Step)

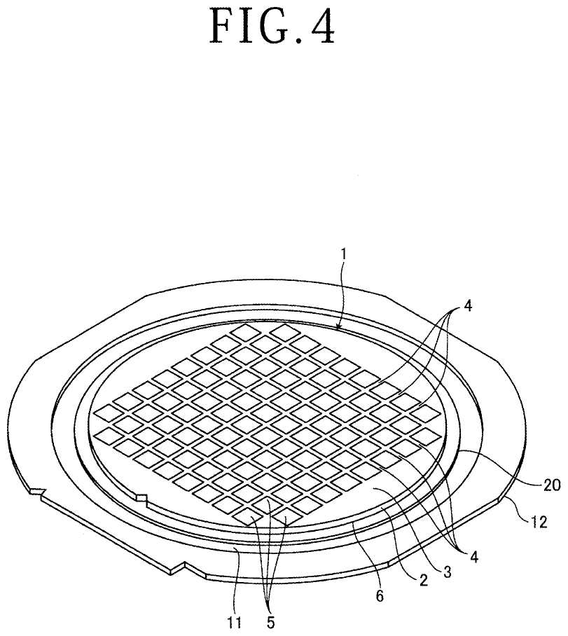

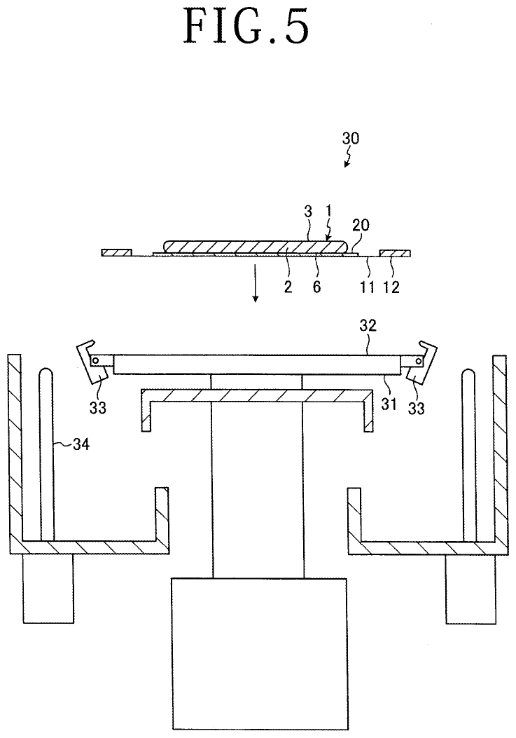

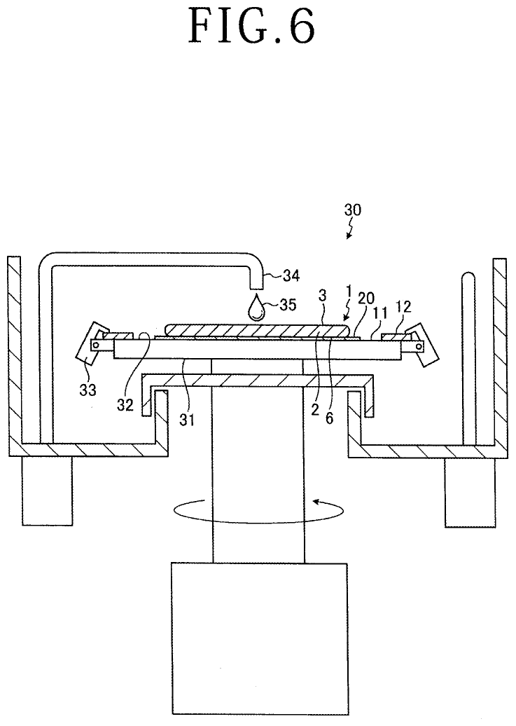

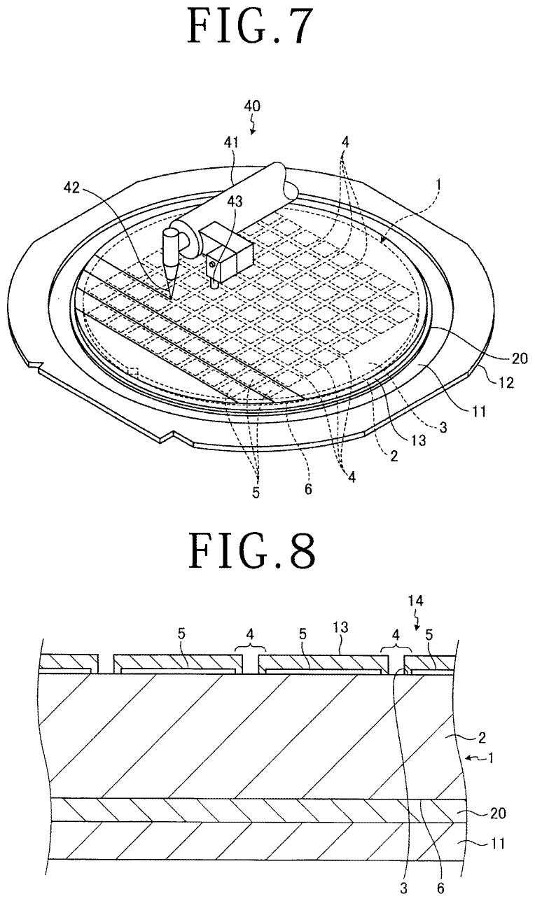

FIG. 4 illustrates in perspective a wafer with a die-attach layer and a tape affixed to a reverse side of a substrate in a preparing step of the method of manufacturing chips illustrated in FIG. 3. FIG. 5 schematically illustrates in cross section the manner in which the wafer is placed onto a spinner table of a protective film applying apparatus in the preparing step of the method of manufacturing chips illustrated in FIG. 3. FIG. 6 schematically illustrates in cross section the manner in which a protective film is formed on a face side of the substrate in the preparing step of the method of manufacturing chips illustrated in FIG. 3. FIG. 7 schematically illustrates in cross section the manner in which part of the protective film on the face side of the substrate is removed in the preparing step of the method of manufacturing chips illustrated in FIG. 3. FIG. 8 illustrates in enlarged fragmentary cross section a wafer unit prepared in the preparing step of the method of manufacturing chips illustrated in FIG. 3.

The preparing step 101 includes the step of preparing a wafer unit 14 (see FIG. 8) in which the wafer 1 is affixed to a circular tape 11 (see FIGS. 4, 5, 6, and 7) with the die-attach layer 20 interposed therebetween, the tape 11 is mounted on an annular frame 12, the devices 5 are protected by a protective film 13 (see FIGS. 7 and 8) as a protective member, and the face side 3 of the substrate 2 is exposed along the projected dicing lines 4.

In the preparing step 101, as illustrated in FIG. 4, the reverse side 6 of the substrate 2 is affixed to the die-attach layer 20 that has been affixed to a central region of the tape 11 that is larger in diameter than the wafer 1, and the annular frame 12 whose inside diameter is larger than the outside diameter of the wafer 1 is affixed to an outer edge portion of the tape 11. The die-attach layer 20 affixed to the reverse side 6 of the substrate 2 is of a circular shape whose diameter is larger than the diameter of the wafer 1 and smaller than the inside diameter of the annular frame 12.

According to the first embodiment, the tape 11 includes a tape referred to as “2in1 tape” in the art. The circular die-attach layer 20 has been affixed to the tape 11 in advance. When the reverse side 6 of the substrate 2 is affixed to the die-attach layer 20, the tape 11 is affixed to the reverse side 6 of the substrate 2 with the die-attach layer 20 interposed therebetween. According to the first embodiment, in the preparing step 101, the reverse side 6 of the substrate 2 is affixed to the die-attach layer 20 that has been affixed to the central region of the tape 11, and the annular frame 12 is affixed to the outer edge portion of the tape 11.

In the preparing step 101, a protective film applying apparatus 30 illustrated in FIG. 5 is used to apply a protective film to the wafer 1. The protective film applying apparatus 30 includes a spinner table 31 having an upper surface functioning as a porous holding surface 32 and a plurality of clamps 33 disposed around the spinner table 31. In operation, the reverse side 6 of the substrate 2 is placed on the holding surface 32 of the spinner table 31 with the die-attach layer 20 and the tape 11 interposed therebetween. Then, the reverse side 6 of the substrate 2 is held under suction on the holding surface 32 with the die-attach layer 20 and the tape 11 interposed therebetween. The annular frame 12 affixed to the tape 11 is gripped in position by the clamps 33 around the spinner table 31. In the preparing step 101, as illustrated in FIG. 6, while the spinner table 31 is being rotated about its central axis, a coating nozzle 34 disposed above the wafer 1 on the spinner table 31 applies a water-soluble resin 35 in liquid phase to the face side 3 of the substrate 2.

The water-soluble resin 35 includes a water-soluble liquid resin such as polyvinyl alcohol (PVA) or polyvinyl pyrrolidone (PVP). The water-soluble resin 35 that has been applied to the face side 3 of the substrate 2 is spread over the face side 3 toward an outer edge of the wafer 1 under centrifugal forces produced by the rotating spinner table 31, covering the entire face side 3. After having coated the face side 3 of the substrate 2 with the water-soluble resin 35, the protective film applying apparatus 30 dries or heats the water-soluble resin 35 to cure the same into the protective film 13 that covers the entire face side 3, i.e., the devices 5.

According to the first embodiment, in the preparing step 101, the water-soluble resin 35 is applied to the face side 3 of the substrate 2 to form the protective film 13 as the protective member. According to the present invention, however, the face side 3 of the substrate 2 may be covered with a water-insoluble resist film as a protective member, so that the resist film as the protective member may be affixed to the face side 3 of the substrate 2.

In the preparing step 101, then, a laser processing apparatus 40 illustrated in FIG. 7 is used to process the wafer 1 with a laser beam. The laser processing apparatus 40 includes a chuck table having a holding surface (not depicted), a laser beam applying unit 41, and an image-capturing camera 43. In operation, the reverse side 6 of the substrate 2 is held under suction on the holding surface of the chuck table with the die-attach layer 20 and the tape 11 interposed therebetween. Then, the image-capturing camera 43 captures an image of the face side 3 of the substrate 2. The laser processing apparatus 40 performs an alignment process for positioning the wafer 1 and the laser beam applying unit 41 with respect to each other on the basis of the captured image.

In the preparing step 101, as illustrated in FIG. 7, while the chuck table and the laser beam applying unit 41 are being relatively moved along each of the projected dicing lines 4, the laser processing apparatus 40 applies a laser beam 42 having a wavelength absorbable by the protective film 13 to the wafer 1 along the projected dicing line 4, removing a portion of the protective film 13 over the projected dicing line 4 thereby to expose a portion of the face side 3 of the substrate 2 at the projected dicing line 4. In the preparing step 101, the laser processing apparatus 40 applies the laser beam 42 to the wafer 1 successively along all the projected dicing lines 4, thereby preparing a wafer unit 14 illustrated in FIG. 8 in which the devices 5 are protected by the protective film 13 and portions of the face side 3 of the substrate 2 are exposed along the projected dicing lines 4.

According to the first embodiment, in the preparing step 101, the laser beam 42 whose wavelength is absorbable by the protective film 13 is applied to the wafer 1 along the projected dicing lines 4, thereby removing portions of the protective film 13 over the projected dicing line 4. According to the present invention, however, a cutting apparatus may have a cutting blade cut into the protective film 13 over the projected dicing lines 4, removing portions of the protective film 13 over the projected dicing line 4 to expose portions of the face side 3 along the projected dicing lines 4.

According to the present invention, the wafer 1 may have a passivation film formed on the face side 3 of the substrate 2 as a protective member that is resistant to both a first plasmatized gas used in the wafer processing step 102 and a second plasmatized gas used in the die-attach layer processing step 103. In case the projected dicing lines 4 are covered with the passivation film, it is preferable to expose the portions of the face side 3 along the projected dicing lines 4 by operating the laser processing apparatus 40 to apply the laser beam 42 to the passivation film over the projected dicing lines 4 or by operating the cutting apparatus to have the cutting blade cut into the passivation film over the projected dicing lines 4. In case the projected dicing lines 4 are not covered with any passivation film, it is not necessary to operate the laser processing apparatus 40 to apply the laser beam 42 to the wafer 1 along the projected dicing lines 4 or to operate the cutting apparatus to have the cutting blade cut into the wafer 1 along the projected dicing lines 4.

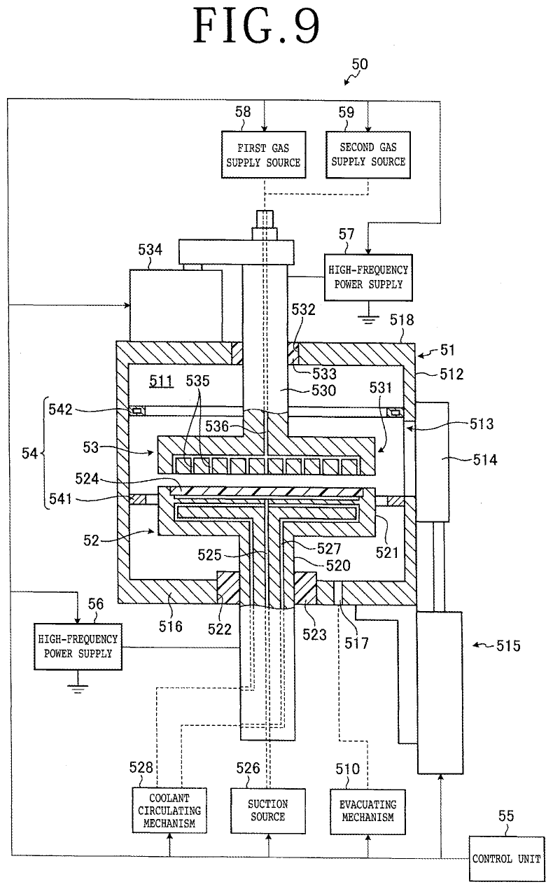

Next, a plasma etching apparatus 50 (see FIG. 9) for performing the wafer processing step 102 and the die-attach layer processing step 103 will be described below with reference to FIG. 9. FIG. 9 schematically illustrates in cross section a structural example of a plasma etching apparatus for carrying out a wafer processing step and a die-attach layer processing step of the method of manufacturing chips illustrated in FIG. 3.

As illustrated in FIG. 9, the plasma etching apparatus 50 includes a chamber 51 in the shape of a rectangular parallelepiped, a porous chuck table 52, an upper electrode 53, a frame fixing unit 54, and a control unit 55.

The chamber 51 has a processing space 511 defined therein for performing plasma etching. The chamber 51 includes an opening 513 defined in a side wall 512 thereof for loading and unloading the wafer unit 14 therethrough and an opening closing door 514 for selectively opening and closing the opening 513. The opening and closing door 514 can be lifted and lowered to open and close the opening 513 by an opening and closing mechanism 515 that includes an air cylinder or the like.

The chamber 51 also includes an evacuation port 517 defined in a bottom wall 516 thereof for providing fluid communication between the inside and outside of the chamber 51. The evacuation port 517 is connected to an evacuating mechanism 510 such as a vacuum pump.

The chuck table 52 and the upper electrode 53 are disposed in vertically facing relation to each other in the processing space 511 in the chamber 51. The chuck table 52 has an upper surface functioning as a porous holding surface for holding the wafer 1 thereon with the tape 17 interposed therebetween. The chuck table 52 is made of an electrically conductive material and also functions as a lower electrode.

The chuck table 52 includes a disk-shaped holder 521 and a cylindrical support 520 protruding downwardly from a central portion of a lower surface of the holder 521. The support 520 is inserted in and extends through an opening 522 defined in the bottom wall 516 of the chamber 51. An annular electrically insulating member 523 is disposed in the opening 522 between the bottom wall 516 and the support 520, electrically insulating the chamber 51 and the chuck table 52 from each other. The chuck table 52 is electrically connected to a high-frequency power supply 56 disposed outside of the chamber 51.

The chuck table 52 has a recess, which is of a circular shape as viewed in plan, defined in an upper surface of the holder 521. A circular thermally conductive sheet 524 is embedded in the recess in the upper surface of the holder 521. The thermally conductive sheet 524 is made of a resin such as acrylic resin or the like or silicone. The thermally conductive sheet 524 should preferably have a thermal conductivity of 2.0 W/m·K or higher. The thermally conductive sheet 524 has an upper surface as part of the holding surface of the chuck table 52. Alternatively, the entire holding surface of the chuck table 52 may be provided by the thermally conductive sheet 524.

The holding surface of the chuck table 52 is connected to a suction source 526 such as an ejector through a fluid channel 525 defined in the chuck table 52. When the wafer 1 is placed on the holding surface of the chuck table 52 with the tape 17 interposed therebetween and is attracted to the holding surface attracts under suction by a suction force from the suction source 526, the wafer 1 is held under suction on the holding surface with the die-attach layer 20 and the tape 17 interposed therebetween.

A cooling fluid channel 527 through which a cooling fluid for cooling the chuck table 52 is defined in the holder 521 and the support 520 of the chuck table 52. The cooling fluid channel 527 has opposite ends connected to a coolant circulating mechanism 528. When the coolant circulating mechanism 528 is actuated, the cooling medium, such as water, circulates through the cooling fluid channel 527 for cooling the chuck table 52.

The upper electrode 53 is made of an electrically conductive material and includes a disk-shaped gas ejector 531 and a cylindrical support 530 protruding upwardly from a central portion of an upper surface of the gas ejector 531. The support 530 is inserted in and extends through an opening 532 defined in a top wall 518 of the chamber 51. An annular electrically insulating member 533 is disposed in the opening 532 between the top wall 518 and the support 530, electrically insulating the chamber 51 and the upper electrode 53 from each other.

The upper electrode 53 is electrically connected to a high-frequency power supply 57 disposed outside of the chamber 51. The support 530 has an upper end connected to a support arm of a lifting and lowering mechanism 534. Therefore, the upper electrode 53 can be lifted and lowered by the lifting and lowering mechanism 534.

The gas ejector 531 has a plurality of ejection ports 535 defined therein and opening at a lower surface thereof. The ejection ports 535 are connected to a first gas supply source 58 and a second gas supply source 59 through a fluid channel 536 defined in the gas ejector 531 and the support 530. The first gas supply source 58 supplies a first gas through the fluid channel 536 to the ejection ports 535 that eject the first gas into the chamber 51. According to the first embodiment, in case the substrate 2 of the wafer 1 is made of silicon, the first gas supply source 58 supplies a fluorine-based gas as the first gas to the chamber 51. The second gas supply source 59 supplies a second gas through the fluid channel 536 to the ejection ports 535 that eject the second gas into the chamber 51. According to the first embodiment, the second gas supply source 59 supplies an oxygen-based gas as the second gas to the chamber 51.

The frame fixing unit 54 is disposed in the processing space 511 in the chamber 51. The frame fixing unit 54 includes an annular frame rest plate 541 whose inside diameter is larger than the outside diameter of the holder 521 of the chuck table 52, an annular frame gripping plate 542 disposed above the frame rest plate 541 and having an inside diameter larger than the outside diameter of the holder 521 of the chuck table 52, and a lifting and lowering mechanism, not depicted, for selectively lifting and lowering the frame gripping plate 542.

The frame rest plate 541 has an upper surface that lies flatwise along horizontal directions. The frame rest plate 541 is fixed to the chamber 51 at a position where the frame rest plate 541 has an upper surface slightly lower than the holding surface of the chuck table 52. The frame gripping plate 542 has a lower surface that lies flatwise along horizontal directions. While the wafer unit 14 is being placed on the chuck table 52, when the frame gripping plate 542 is lowered by the lifting and lowering mechanism, the upper surface of the frame rest plate 541 and the lower surface of the frame gripping plate 542 grip the annular frame 12 of the wafer unit 14.

The control unit 55 controls the various components of the plasma etching apparatus 50 to perform plasma etching on the wafer 1. The control unit 55 includes a computer including an arithmetic processing device having a microprocessor such as a central processing unit (CPU), a storage device having a memory such as a read only memory (ROM) or a random access memory (RAM), and an input/output interface device. The arithmetic processing device of the control unit 55 performs an arithmetic processing sequence according to computer programs stored in the storage device to generate and output control signals for controlling the plasma etching apparatus 50 to the components of the plasma etching apparatus 50 through the input/output interface device.

To the control unit 55, there are electrically connected a display unit such as a liquid crystal display device for displaying various items of information and images and an input unit for registering processing content information entered by the operator of the plasma etching apparatus 50. The input unit includes at least one of a touch panel incorporated in the display unit and an external input device such as a keyboard.

(Wafer Processing Step)

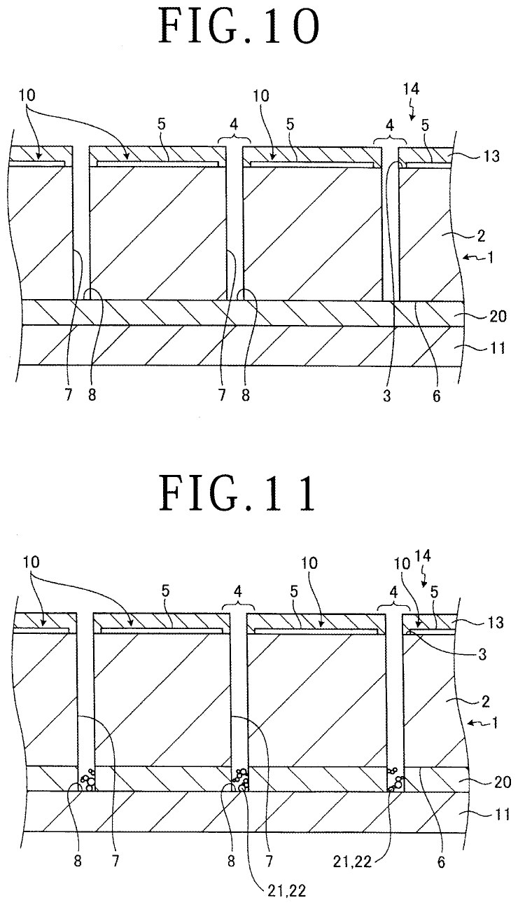

FIG. 10 illustrates in enlarged fragmentary cross section the wafer unit after the wafer processing step of the method of manufacturing chips illustrated in FIG. 3. The wafer processing step 102 is a step of supplying the first gas to the wafer unit 14 to perform plasma etching on the wafer 1 from the face side 3 of the substrate 2, thereby dividing the wafer 1 along the projected dicing lines 4 to expose the die-attach layer 20. In the wafer processing step 102, specifically, the lifting and lowering mechanism 534 of the plasma etching apparatus 50 lifts the upper electrode 53 and the lifting and lowering mechanism lifts the frame gripping plate 542. When the upper electrode 53 and the frame gripping plate 542 have been lifted, the opening and closing mechanism 515 lowers the opening and closing door 514, opening the opening 513.

In the wafer processing step 102, the wafer unit 14 that has been prepared in the preparing step 101 is loaded into the processing space 511 in the chamber 51 by a delivery unit, not depicted, the wafer 1 is placed on the holding surface of the chuck table 52 with the die-attach layer 20 and the tape 11 interposed therebetween, and the annular frame 12 is placed on the upper surface of the frame rest plate 541 with the tape 11 interposed therebetween. In the wafer processing step 102, then, the suction source 526 is actuated to apply a suction force to the holding surface of the chuck table 52 to hold the reverse side 6 of the wafer 1 under suction on the holding surface with the die-attach layer 20 and the tape 11 interposed therebetween, and the lifting and lowering mechanism lowers the frame gripping plate 542 toward the frame rest plate 541 until the annular frame 12 is gripped securely in position between the frame gripping plate 542 toward the frame rest plate 541.

In the wafer processing step 102, the opening and closing mechanism 515 lifts the opening and closing door 514 to close the opening 513, and the evacuating mechanism 510 is actuated to depressurize the chamber 51, creating a vacuum state, i.e., a low-pressure, in the processing space 511. The coolant circulating mechanism 528 is actuated to circulate the coolant such as water through the cooling fluid channel 527, thereby preventing the chuck table 52 from having abnormal temperature rises. In the wafer processing step 102, further, the lifting and lowering mechanism 534 lowers the upper electrode 53 toward the chuck table 52 until the lower surface of the upper electrode 53 and the wafer 1 held on the chuck table 52 functioning as the lower electrode are spaced apart from each other by a predetermined interelectrode distance that is suitable for plasma etching in the processing space 511.

As the processing space 511 is progressively depressurized, the suction force applied from the suction source 526 and acting on the wafer 1 is reduced, possibly making the wafer 1 less attracted under suction to the chuck table 52. However, while the processing space 511 is being depressurized, the annular frame 12 is secured in position by the frame fixing unit 54, keeping the tape 17 pressed against the holding surface of the chuck table 52. In the depressurized environment, therefore, the wafer unit 14 remains appropriately held on the chuck table 52.

In the wafer processing step 102, moreover, the first gas supply source 58 supplies the first gas at a predetermined rate to the gas ejector 531 that ejects the first gas through the ejection ports 535 toward the wafer 1 held on the chuck table 52. Then, while the first gas supply source 58 is thus supplying the first gas, the high-frequency power supply 57 applies high-frequency electric power to the upper electrode 53 for generating and maintaining a plasma in the processing space 511, and the high-frequency power supply 56 applies high-frequency electric power to the chuck table 52 as the lower electrode for drawing in ions.

The first gas in a space between the chuck table 52 and the upper electrode 53 is plasmatized and pulled toward the wafer 1, performing etching, i.e., plasma etching, on the portions of the face side 3 of the substrate 2 at the projected dicing lines 4 that are exposed from the protective film 13 to form dividing grooves 7 (see FIG. 10) in the face side 3 along the projected dicing lines 4. As the plasma etching is in progress, the dividing grooves 7 are progressively deepened in the substrate 2 toward the reverse side 6 thereof.

According to the first embodiment, in case the substrate 2 of the wafer 1 is made of silicon, the first gas includes a fluorine-based gas such as SF₆, C₄F₈, or CF₄. However, the first gas is not limited to these examples. Further, a single first gas may be supplied or two first gases, e.g., SF₆ and C₄F₈, may alternately be supplied to the processing space 511.

In the wafer processing step 102, the plasma etching apparatus 50 operates for a preset period of time to perform plasma etching on the substrate 2 of the wafer 1 depending on the thickness of the substrate 2. Specifically, the plasma etching apparatus 50 applies high-frequency electric power to the chuck table 52 and the upper electrode 53 while supplying the first gas to the processing space 511 for the preset period of time, completely removing the portions of the substrate 2 along the projected dicing lines 4 that are exposed from the protective film 13 thereby to divide the wafer 1 into individual chips 10 and expose the die-attach layer 20 at respective bottoms 8 of the dividing grooves 7.

### (Die-Attach Layer Processing Step)

FIG. 11 illustrates in enlarged fragmentary cross section the wafer unit 14 after the die-attach layer processing step of the method of manufacturing chips illustrated in FIG. 3. The die-attach layer processing step 103 is a step of, after the wafer processing step 102, supplying the second gas to the wafer unit 14 to perform plasma etching on the die-attach layer 20 from the face side 3 of the substrate 2. In the die-attach layer processing step 103, specifically, the second gas supply source 59 supplies the second gas at a predetermined rate to the gas ejector 531 that ejects the second gas through the ejection ports 535 toward the wafer 1 held on the chuck table 52.

Then, in the die-attach layer processing step 103, while the second gas supply source 59 is thus supplying the second gas, the high-frequency power supply 57 applies high-frequency electric power to the upper electrode 53 for generating and maintaining a plasma in the processing space 511, and the high-frequency power supply 56 applies high-frequency electric power to the chuck table 52 as the lower electrode for drawing in ions. The second gas in a space between the chuck table 52 and the upper electrode 53 is plasmatized and pulled toward the wafer 1, performing etching, i.e., plasma etching, on the resin of the portions of the die-attach layer 20 at the projected dicing lines 4 that are exposed at the bottoms 8 of the dividing grooves 7 in the substrate 7. As the plasma etching is in progress, the dividing grooves 7 are progressively deepened in the die-attach layer 20 toward the tape 11.

According to the first embodiment, in case the die-attach layer 20 is made of an acrylic resin or an epoxy resin, the second gas includes an oxygen-based gas such as O₂. However, the second gas is not limited to this example.

In the die-attach layer processing step 103, the plasma etching apparatus 50 operates for a preset period of time to perform plasma etching on the resin of the die-attach layer 20 depending on the thickness of the die-attach layer 20. Specifically, the plasma etching apparatus 50 applies high-frequency electric power to the chuck table 52 and the upper electrode 53 while supplying the second gas to the processing space 511 for the preset period of time, removing the portions of the substrate 2 along the projected dicing lines 4 that are exposed from the protective film 13 and the resin of the portions of the die-attach layer 20 at the respective bottoms 8 of the dividing grooves 7. When the resin of the portions of the die-attach layer 20 has been removed by the plasma etching, fillers 21 of the die-attach layer 20 and the resin between the fillers 21 are left on the bottoms 8 of the dividing grooves 7. The fillers 21 of the die-attach layer 20 and the resin between the fillers 21 that have been left on the bottoms 8 of the dividing grooves 7 will hereinafter be referred to as “filler residuals 22.”

(Cleaning Step)

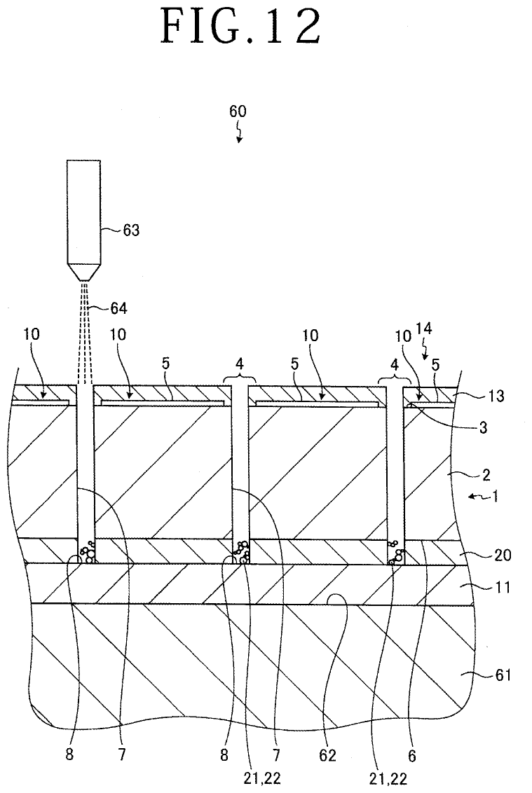

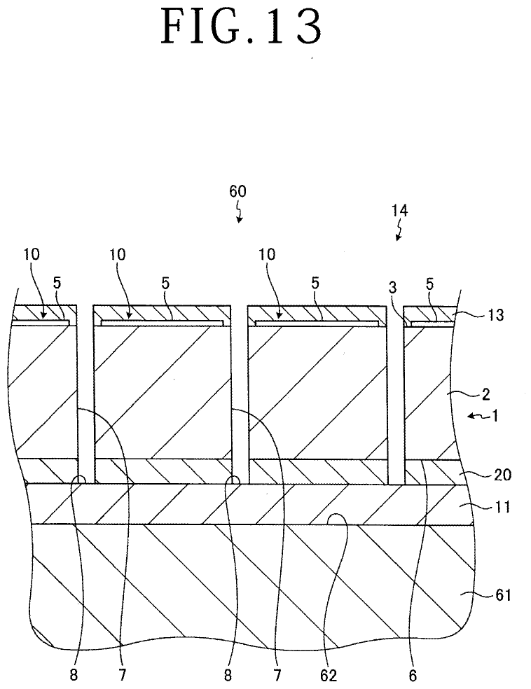

FIG. 12 illustrates in enlarged fragmentary cross section the wafer illustrating a cleaning step of the method of manufacturing chips illustrated in FIG. 3. FIG. 13 illustrates in enlarged fragmentary cross section the wafer from which filler residuals remaining on the bottoms of dividing grooves have been removed in the cleaning step of the method of manufacturing chips illustrated in FIG. 3.

The cleaning step 104 is a step of, after the die-attach layer processing step 103, removing the filler residuals 22 remaining on the bottoms 8 of dividing grooves 7 in the die-attach layer processing step 103 along the projected dicing lines 4 by ejecting cleaning water 64 as a fluid to the face side 3 of the substrate 1 of the wafer unit 14.

The cleaning step 104 is carried out by a cleaning apparatus 60 illustrated in FIG. 12 that includes a table 61 having a porous holding surface 62 and a cleaning water nozzle 63 for ejecting cleaning water 64. In the cleaning step 104, the reverse side 6 of the substrate 2 of the wafer 1 is placed on the holding surface 62 of the table 61 with the die-attach layer 20 and the tape 11 interposed therebetween. While the face side 3 of the substrate 2 is facing upwardly, the reverse side 6 thereof is held under suction on the holding surface 62 of the table 61 with the die-attach layer 20 and the tape 11 interposed therebetween. In the cleaning step 104, then, while the wafer 1 held under section on the holding surface 62 and the cleaning water nozzle 63 above the table 61 are being moved relatively to each other successively along the dividing grooves 7 formed in the wafer 1 along the projected dicing lines 4, the cleaning water nozzle 63 of the cleaning apparatus 60 ejects the cleaning water 64 to the wafer 1 along the dividing grooves 7 and into the dividing grooves 7 toward the bottoms 8 thereof, as illustrated in FIG. 12.

As illustrated in FIG. 13, the cleaning water 64 ejected from the cleaning water nozzle 63 into the dividing grooves 7 toward the bottoms 8 thereof peels off the filler residuals 22 from the tape 11 at the bottoms 8 of the dividing grooves 7, removing the filler residuals 22 from the dividing grooves 7 and hence the wafer unit 14. In the cleaning step 104, the remaining filler residuals 22 are removed from the bottoms 8 of the dividing grooves 7, dividing the die-attach layer 20 into pieces belonging to the respective individual chips 10. In the cleaning step 104, the cleaning water nozzle 63 of the cleaning apparatus 60 ejects the cleaning water 64 into all the dividing grooves 7 toward the bottoms 8 thereof.

According to the first embodiment, since the cleaning water 64 is ejected along the dividing grooves 7, the cleaning water 64 finds its way easily into the dividing grooves 7 and to the bottoms 8 thereof, making it easy to remove the filler residuals 22. Further, according to the present invention, the table 61 may be rotated about its central axis to clean the entire surface of the wafer 1 with the cleaning water 64 ejected thereto from the cleaning water nozzle 63. The rotation of the table 61 makes it possible to carry out the cleaning step 104 and the mask removing step 105 at the same time.

(Mask Removing Step)

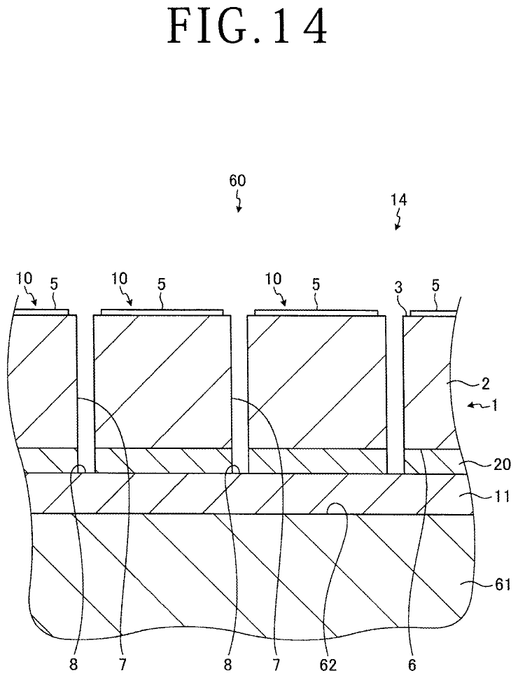

FIG. 14 illustrates in enlarged fragmentary cross section the wafer after the mask removing step of the method of manufacturing chips illustrated in FIG. 3. The mask removing step 105 is a step of cleaning the face side 3 of the substrate 2 to remove the protective film 13 after the wafer processing step 102 and the die-attach layer processing step 103. In the mask removing step 105, while the table 61 is being rotated about its central axis, the cleaning water nozzle 63 ejects the cleaning water 64 to the face side 3 of the substrate 2 while at the same time moving above the wafer 1 along the holding surface 62.

The cleaning water 64 may include pressurized pure water or a two-fluid mixture of pressurized pure water and pressurized gas. The cleaning water 64 ejected to the face side 3 of the substrate 2 is spread over the face side 3 toward an outer edge of the wafer 1 under centrifugal forces produced by the rotating table 61, and flows over the face side 3 to remove the protective film 13 of the water-soluble resin from the face side 3 of the substrate 2, as illustrated in FIG. 14. In the mask removing step 105, the cleaning apparatus 60 dries the face side 3 of the substrate 2 after the removal of the protective film 13.

According to the first embodiment, in the cleaning step 104, the cleaning water 64 as a fluid is ejected to the wafer 1 along the dividing grooves 7 and into the dividing grooves 7 toward the bottoms 8 thereof, as described above.

According to the first embodiment, in case the protective film 13 that protects the devices 5 is made of a water-soluble resin, after the die-attach layer 20 has been divided in the cleaning step 104, the cleaning water 64 is supplied to the face side 3 of the substrate 2 to remove the protective film 13 in the mask removing step 105. According to the present invention, however, in case the wafer 1 has a passivation film as a protective member, the protective member is not removed.

### (Picking-Up Step)

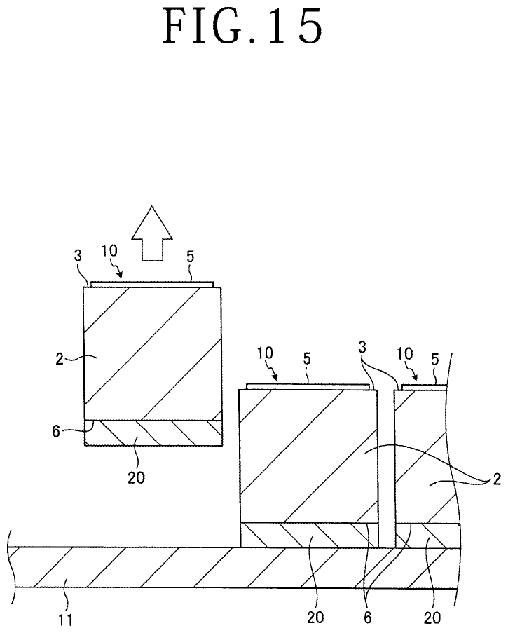

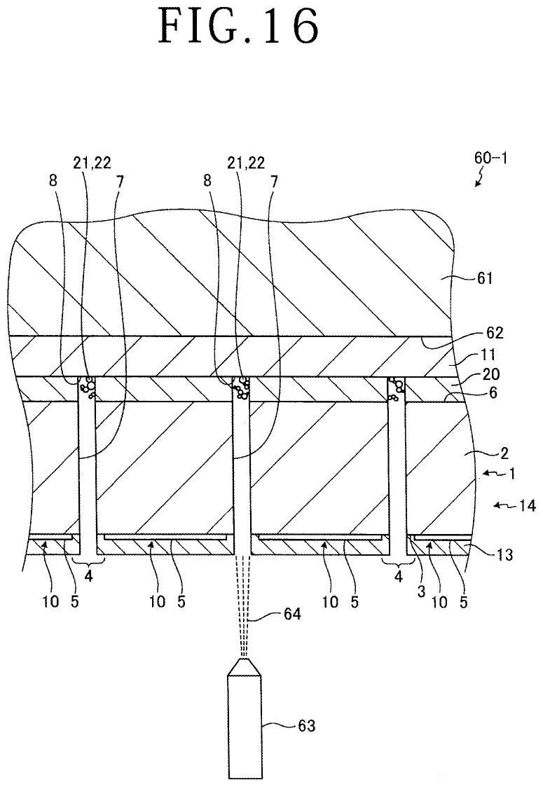

FIG. 15 illustrates in enlarged fragmentary cross sectional the wafer illustrating the picking-up step of the method of manufacturing chips illustrated in FIG. 3. The picking-up step 106 is a step of picking up the individual chips 10 after the cleaning step 104. According to the first embodiment, in the picking-up step 106, a known pickup, not depicted, picks up the chips 10 one by one from the tape 11, as illustrated in FIG. 15.

Generally, the die-attach layer 20 is made of a resin such as an acrylic resin or an epoxy resin, and contains fillers 21 of silica, aluminum oxide, or SiC for achieving a desired level of viscosity at the time of mounting the chips 10 on boards. The applicant of the present invention has found that an oxygen-based gas used as an etching gas for a resin such as an acrylic resin or an epoxy resin is unable to etch the fillers 21, and the die-attach layer 20 cannot fully be divided by plasma etching because the fillers 21 and the resin between adjacent ones of the fillers 21 are left as the filler residuals 22.

In the method of manufacturing chips according to the first embodiment, as described above, after plasma etching has been performed on the die-attach layer 20 with the second gas that includes an oxygen-based gas, the cleaning water 64 as a fluid is ejected to the filler residuals 22, peeling off the filler residuals 22 from the wafer unit 14 in the cleaning step 104. In the method of manufacturing chips according to the first embodiment, therefore, the die-attach layer 20 can be divided along the projected dicing lines 4 in the cleaning step 104, for thereby fabricating the chips 10 each with the laminated die-attach layer 20.

As a consequence, the method of manufacturing chips according to the first embodiment is advantageous in that since the chips 10 each with the laminated die-attach layer 20 can be fabricated by dividing the die-attach layer 20 along the projected dicing lines 4 in the cleaning step 104 in which the face side 3 of the substrate 2 is cleaned to remove the protective film 13, the number of working steps required to manufacture the chips 10 each with the laminated die-attach layer 20 is prevented from increasing.

Further, in the method of manufacturing chips according to the first embodiment, inasmuch as the cleaning water 64 is ejected to the wafer 1 along the projected dicing lines 4 in the cleaning step 104 in which the face side 3 of the substrate 2 is cleaned to remove the protective film 13, the filler residuals 22 can reliably be peeled off from the tape 11 at the bottoms 8 of the dividing grooves 7 formed along the projected dicing lines 4.

### (Modification)

A method of manufacturing chips according to a modification of the first embodiment will be described below with reference to the drawings. FIG. 16 illustrates in enlarged fragmentary cross section a cleaning step of the method of manufacturing chips according to a modification of the first embodiment. Those components illustrated in FIG. 16 that are identical to those according to the first embodiment are denoted by identical reference signs, and will be omitted from description. In the cleaning step 104 and the mask removing step 105 of the method of manufacturing chips according to the modification of the first embodiment, the holding surface 62 of the table 61 of a cleaning apparatus 60-1 illustrated in FIG. 16 faces downwardly and the cleaning water nozzle 63 is disposed below the table 61, and with the face side 3 of the substrate 2 facing downwardly, the reverse side 6 thereof is held under suction on the holding surface 62 of the table 61 with the die-attach layer 20 and the tape 11 interposed therebetween.

In the cleaning step 104 and the mask removing step 105, the table 61 is rotated about its central axis, and while the cleaning water nozzle 63 below the table 61 is being oscillated in radial directions of the wafer 1, the cleaning water nozzle 63 ejects the cleaning water 64 toward the wafer 1. In the cleaning step 104 and the mask removing step 105, the cleaning water 64 ejected from the cleaning water nozzle 63 peels off the filler residuals 22 from the tape 11 at the bottoms 8 of the dividing grooves 7, removing the filler residuals 22 from the dividing grooves 7 and hence the wafer unit 14 thereby to divide the die-attach layer 20 into pieces belonging to the respective individual chips 10. According to the modification, in the cleaning step 104, with the face side 3 of the substrate 2 facing downwardly, the cleaning water 64 is ejected toward the face side 3 of the substrate 2. According to the modification, therefore, in the cleaning step 104 and the mask removing step 105, the filler residuals 22 removed from the wafer unit 14 drop downwardly. Further, in the cleaning step 104 and the mask removing step 105, the cleaning apparatus 60 removes the protective film 13 from the face side 3 of the substrate 2 with the cleaning water 64, and dries the face side 3 of the substrate 2.

In the cleaning step 104 of the method of manufacturing chips according to the modification of the first embodiment, while the wafer 1 held under suction on the holding surface 62 and the cleaning water nozzle 63 below the table 61 are being moved relatively to each other successively along the dividing grooves 7 formed in the wafer 1 along the projected dicing lines 4, the cleaning water nozzle 63 ejects the cleaning water 64 to the wafer 1 along the dividing grooves 7 and into the dividing grooves 7 toward the bottoms 8 thereof, and peels off the filler residuals 22 from the tape 11 at the bottoms 8 of the dividing grooves 7, removing the filler residuals 22 from the dividing grooves 7 and hence the wafer unit 14 to divide the die-attach layer 20 into pieces belonging to the respective individual chips 10. In the mask removing step 105, the table 61 should desirably be rotated about its central axis, and while the cleaning water nozzle 63 is being moved along the holding surface 62 below the wafer 1, the cleaning water nozzle 63 should desirably eject the cleaning water 64 to the face side 3 of the substrate 2, thereby removing the protective film 13 from the face side 3 of the substrate 2 and drying the face side 3 of the substrate 2, as with the first embodiment.

In the method of manufacturing chips according to the modification, after plasma etching has been performed on the die-attach layer 20 with the second gas that includes an oxygen-based gas, the cleaning water 64 as a fluid is ejected to the filler residuals 22 to peel off the filler residuals 22 from the tape 11 and remove the filler residuals 22 from the wafer unit 14 in the cleaning step 104. As a result, the method of manufacturing chips according to the modification can divide the die-attach layer 20 along the projected dicing lines 4 to fabricate the chips 10 each with the laminated die-attach layer 20 in the cleaning step 104, as with the first embodiment, so that the number of working steps required to manufacture the chips 10 each with the laminated die-attach layer 20 is prevented from increasing.

Moreover, in the cleaning step 104 of the method of manufacturing chips according to the modification, with the face side 3 of the substrate 2 facing downwardly, the cleaning water 64 is ejected toward the face side 3 of the substrate 2. Therefore, in the cleaning step 104, the filler residuals 22 removed from the wafer unit 14 drop downwardly. As a result, in the method of manufacturing chips according to the modification, the possibility that the filler residuals 22 will be attached to the face side 3 of the substrate 2, i.e., the chips 10, is minimized, and the possibility that the face side 3 of the substrate 2, i.e., the chips 10, will be damaged by the filler residuals 22 is minimized.

The present invention is not limited to the above embodiment, and various changes and modifications may be made therein without departing from the scope of the present invention. According to the present invention, for example, in the wafer processing step 102 and the die-attach layer processing step 103, rather than plasmatizing the first and second gases in the processing space 511 by applying high-frequency electric power to the chuck table 52 as the lower electrode and the upper electrode 53, the first and second gases that have been plasmatized in a remote plasma source may be introduced into the processing space 511 in the chamber 51 of a remote-plasma-type plasma etching apparatus.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of manufacturing chips with laminated die-attach layers, comprising:
a preparing step of preparing a wafer unit in which a wafer having a plurality of devices formed in respective areas demarcated on a face side thereof by a plurality of intersecting projected dicing lines established thereon is affixed to a tape with a die-attach layer being interposed therebetween, the die-attach layer including fillers, and the devices are protected by a protective member and the face side of the wafer is exposed along the projected dicing lines;
a wafer processing step of supplying a first gas to the wafer unit and performing plasma etching on the wafer from the face side thereof to divide the wafer and expose the die-attach layer along the projected dicing lines;
after the wafer processing step, a die-attach layer processing step of supplying a second gas to the wafer unit and performing plasma etching on the die-attach layer from the face side of the wafer; and
after the die-attach layer processing step, a cleaning step of ejecting a fluid to the face side of the wafer to remove filler residuals that have remained along the projected dicing lines in the die-attach layer processing step from the wafer unit.

2. The method of manufacturing chips according to claim 1, wherein the cleaning step includes the step of ejecting the fluid to the face side of the wafer along the projected dicing lines.

3. The method of manufacturing chips according to claim 1, wherein the cleaning step includes the step of ejecting the fluid to the face side of the wafer while the face side of the wafer is facing downwardly.
